(19) United States
(12) Patent Application Publication
(10) Pub. No.: US 2012/0167979 A1
(43) Pub. Date: Jul. 5, 2012

(54) THIN FILM SOLAR CELL AND METHOD FOR MANUFACTURING THE SAME

(75) Inventors: Dung-Ching PERNG, Tainan City (TW); Jia-Feng FANG, Yuanlin Township (TW)

(73) Assignee: NATIONAL CHENG KUNG UNIVERSITY, Tainan City (TW)

(21) Appl. No.: 13/341,378

(22) Filed: Dec. 30, 2011

(30) Foreign Application Priority Data
Dec. 30, 2010 (TW) 099146943

(51) Int. Cl. H01L 31/0224; H01L 31/18

(52) U.S. Cl. 136/256; 438/95; 257/E31.126

(57) ABSTRACT

The present invention provides a thin film solar cell, which comprises: a substrate; a first electrode disposed on the substrate; a barrier layer disposed on the first electrode, wherein the material of the barrier layer is a conductive material; an ohmic contacting layer disposed on the barrier layer; an absorption layer disposed on the ohmic contacting layer; a buffer layer disposed on the absorption layer; a transparent conductive layer disposed on the buffer layer; and a second electrode disposed on the transparent conductive layer. In addition, the present invention also provides a method for manufacturing the aforementioned thin film solar cell.

### CROSS REFERENCE TO RELATED APPLICATION

This application claims the benefits of the Taiwan Patent Application Serial Number 99146943, filed on Dec. 30, 2010, the subject matter of which is incorporated herein by reference.

### BACKGROUND OF THE INVENTION

1. Field of the Invention

The present invention relates to a thin film solar cell and a method for manufacturing the same and, more particularly to a CuInSe₂ (CIS)-based thin film solar cell and a method for manufacturing the same.

2. Description of Related Art

With the development of industrial technology, the worldwide problems of the energy crisis and environmental pollution are getting more and more serious. In order to solve these problems, solar cells, which can convert solar energy into electricity, are considered as alternative energy supplement devices. During the process of converting solar energy into electricity, there are no greenhouse gases such as carbon dioxide and pollution generated, so solar cells are also considered as environmental friendly energy supplement devices. Currently, many types of solar cells manufactured with different materials have been developed, such as Si-based solar cells, dye-sensitized solar cells, and organic cells.

Among these solar cells, CuInSe₂-based solar cells, which use CuInGaSe₂ or CuInAlSe₂ thin film as an absorption layer, have high absorption efficiency, high conversion efficiency, and exhibit good stability under outdoor environments. Hence, such CIS-based solar cells are considered as next generation solar cells.

The structure of the conventional CIS-based solar cell is shown in FIG. 1, which comprises: a substrate 11; and a back electrode 12, a p-type absorption layer 13, an n-type buffer layer 14, a transparent conductive layer 15, and an upper electrode 16 sequentially laminated from bottom to top on the substrate 11.

During the process for manufacturing the CIS-based solar cell, and in general the material of the back electrode 12 is Mo, and the p-type absorption layer 13 can be formed by co-evaporating, coating or depositing metallic precursors and then performing a selenization process. During the selenization process, the back electrode 12 may react with selenium (Se), and a Mo selenide such as MoSe₂ may self-formed at the interface between the back electrode 12 and the p-type absorption layer 13. MoSe₂ can provide ohmic contact to the back electrode 12, but thick Mo film can be transformed to MoSe₂ layer if high-temperature and high-pressure with a long selenization process is used. In this case, the thick MoSe₂ layer may cause high series resistance of the solar cell. In addition, the thick MoSe₂ layer may also influence the adhesion of the absorption layer and could result in peeling of the absorption layer. Although the problems of converting too thick of Mo layer to MoSe₂ can be prevented by performing a low-pressure selenization process, the absorption layer usually consists of small grains and having a rough surface in such a low-pressure process. The rough surface of the absorption layer may cause un-even or no coverage of the buffer layer, which may induce high leakage current and low conversion efficiency of the solar cells. In addition, if the absorption layer consists of small grains, it will increase the grain boundaries significantly which can also causing higher carrier combinations, and resulting in a lower conversion efficiency of the solar cells.

Therefore, it is desirable to provide a thin film solar cell and a method for manufacturing the same, which not only favor the growth of the absorption layer but also can control the thickness of the self-formed MoSe₂ layer. When the MoSe₂ layer with a suitable thickness is obtained, the increase of the series resistance and the peeling of the absorption layer can be prevented when a high quality absorption layer with a smooth surface can be formed the conversion efficiency of the solar cells can be further improved.

### SUMMARY OF THE INVENTION

The object of the present invention is to provide a thin film solar cell, wherein the ohmic contacting layer (i.e. the MoSe₂ layer) thereof has a suitable thickness.

Another object of the present invention is to provide a method for manufacturing a thin film solar cell, wherein a barrier layer and a Mo-containing layer are sequentially formed on a back electrode (i.e. a first electrode) to adjust the thickness of the ohmic contacting layer.

To achieve the object, the thin film solar cell of the present invention comprises: a substrate; a first electrode disposed on the substrate; a barrier layer disposed on the first electrode, wherein the material of the barrier layer is a conductive material; an ohmic contacting layer disposed on the barrier layer; an absorption layer disposed on the ohmic contacting layer; a buffer layer disposed on the absorption layer; a transparent conductive layer disposed on the buffer layer; and a second electrode disposed on the transparent conductive layer.

In addition, the method for manufacturing a thin film solar cell of the present invention comprises the following steps: (A) providing a substrate; (B) forming a first electrode on the substrate; (C) forming a barrier layer on the first electrode, wherein the material of the barrier layer is a conductive material; (D) forming a Mo-containing layer on the barrier layer; (E) forming an absorption-layer precursor on the Mo-containing layer, and performing a selenization process or a sulfation process to transfer the absorption-layer precursor and the Mo-containing layer into an absorption layer and an ohmic contacting layer respectively; (F) forming a buffer layer on the absorption layer; (G) forming a transparent conductive layer on the buffer layer; and (H) forming a second electrode on the transparent conductive layer. In addition, the present invention further comprises step (F1) after step (F): forming an i-ZnO thin layer on the buffer layer, in order to reduce leakage current.

According to the method for manufacturing a thin film solar cell of the present invention, a barrier layer and a Mo-containing layer are interposed between the first electrode (i.e. a Mo back electrode) and the absorption layer, wherein the barrier layer does not react with Se or S. The barrier layer also has conductivity, so it can be used as a material for the electrode of the thin film solar cell. In addition, the barrier layer can further prevent Se diffusing into the first electrode, and prevent the first electrode from becoming over-selenized during the selenization process. In addition, a thicker ohmic contacting layer may also cause higher series resistance of the solar cell. Hence, when the method of the present invention is used to manufacture a thin film solar cell, the Mo-containing layer can be used to adjust the thickness of the ohmic contacting layer (i.e. the MoSe₂ layer). Therefore, the thickness of the ohmic contacting layer of the obtained thin film solar cell can be controlled in a suitable range.

According to the method for manufacturing a thin film solar cell of the present invention, an ohmic contacting layer with a suitable thickness can be obtained at a high selenization temperature and a high Se pressure during the selenization process. When an ohmic contacting layer with a well-controlled thickness is obtained, the problem of the peeling of the absorption layer can be prevented, and the process yield of the thin film solar cells can further be improved. In addition, when the method of the present invention is used to manufacture a thin film solar cell, the obtained solar cell has an absorption layer with good crystallization and a smooth CIGS surface morphology, so the buffer layer, the i-ZnO thin layer, and the transparent conductive layer can cover the absorption layer completely. Hence, the leakage current and the carrier recombination probability can be reduced, and therefore the carrier collection and the photoelectron conversion efficiency can further be increased.

According to the thin film solar cell and the method for manufacturing the same of the present invention, the material of the barrier layer may be Al, La, Ta, Ir, Os, or an alloy thereof. Preferably, the material of the barrier layer is Al, La, or an alloy thereof. More preferably, the material of the barrier layer is doped with B, Al or Ga. During the selenization process, the high selenization temperature can make the doping element appropriately diffuse into the absorption layer, so a graded doping can be obtained and an absorption layer with a graded bandgap can further be obtained. The graded bandgap can boost the backside electric field to reduce the carrier recombination probability and improve the carrier collection. Herein, the barrier layer can not only prevents Se diffusing into the first electrode, but also serves as an electrode due the conductivity of the barrier layer.

In addition, according to the method for manufacturing the thin film solar cell of the present invention, the Mo-containing layer is a Mo layer. Hence, the ohminc contacting layer of the obtained thin film solar cell is a MoSe₂ layer. Herein, the thickness of the ohmic contacting layer may be 1-150 nm. Preferably, the thickness of the ohmic contacting layer is 1-100 nm. More preferably, the thickness of the ohmic contacting layer is 20-70 nm.

Furthermore, the thin film solar cell of the present invention may further comprise an Al-doped Mo layer, which is disposed between the substrate and the first electrode. When the substrate is a glass substrate, a high selenization temperature and a high Se pressure can induce Al to diffuse into the glass substrate during the selenization process, so a layer of Al₂O₃ is formed between the substrate and the Al-doped Mo layer. Herein, Al₂O₃ can increase the adhesion between the first electrode and the substrate.

According to the method for manufacturing the thin film solar cell of the present invention, the material of the first electrode can be any electrode material generally used in the art. Preferably, the first electrode is a Mo electrode.

In addition, according to the method for manufacturing the thin film solar cell of the present invention, the substrate can be a rigid substrate or a flexible substrate, such as a glass substrate, a metal substrate, or a plastic substrate. Herein, the metal substrate may be a stainless substrate, a Ti substrate, a Cu substrate, or a Mo substrate, and the plastic substrate may be a rubber substrate, a polyethylene naphthalate (PEN) substrate, or a poly(ethylene terephthalate) (PET) substrate.

According to the method for manufacturing the thin film solar cell of the present invention, the absorption layer may be a CIS absorption layer, a CIGS absorption layer, a CZTS absorption layer, or a CIAS absorption layer. Furthermore, the transparent conductive layer can be ITO, ZnO doped with Al, or ZnO doped with In.

Other objects, advantages, and novel features of the invention will become more apparent from the following detailed description when taken in conjunction with the accompanying drawings.

### BRIEF DESCRIPTION OF THE DRAWINGS

FIG. 1 is a cross-sectional view of a conventional CIS-based thin film solar cell; and

FIGS. 2A-2E are cross-sectional views showing the process for manufacturing the thin film solar cell according to Embodiment 1 of the present invention.

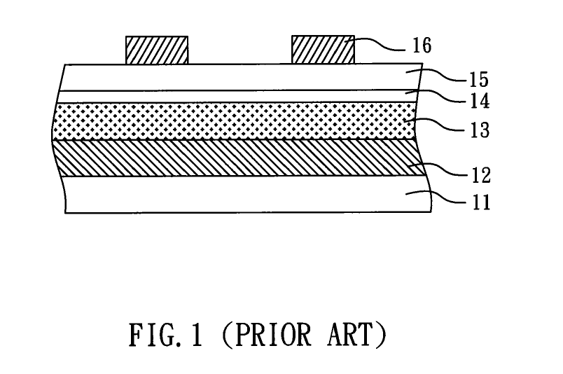

### DETAILED DESCRIPTION OF THE PREFERRED EMBODIMENT

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

### Embodiment 1

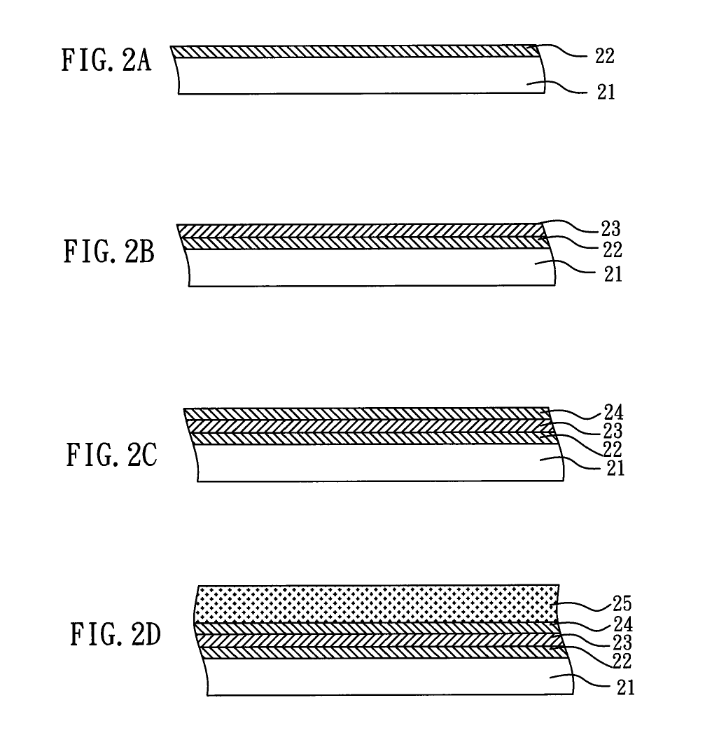

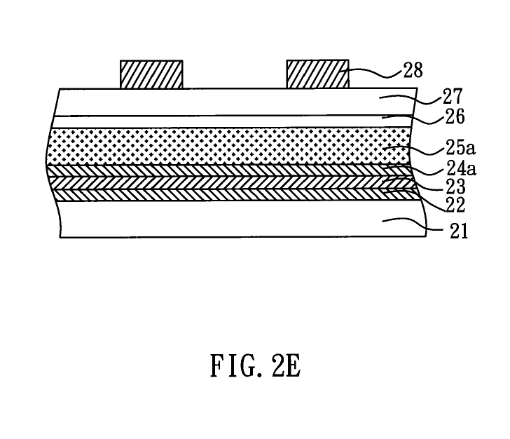

With reference to FIG. 2A, a substrate 21 was provided, and a Mo layer was formed on the substrate 21 by a sputtering process. The obtained Mo layer was used as a first electrode 22. In the present embodiment, the substrate 21 is a glass substrate.

Then, as shown in FIG. 2B, a barrier layer 23 was deposited on the first electrode 22 with a sputtering process or an evaporation process. The material of the barrier layer 23 was a conductive material, which cannot easily react with Se or S. In the present embodiment, the material of the barrier layer 23 was Al. The barrier layer 23 can not only prevent the material of the first electrode 22 from transferring into Se compounds or S compounds during the selenization process or the sulfation process, but also be used as an electrode material due to the conductivity of the barrier layer 23.

With reference to FIG. 2C, a Mo-containing layer 24 was deposited on the barrier layer 23 with a sputtering process. In the present embodiment, the Mo-containing layer 24 was a Mo layer, and the thickness of the Mo-containing layer 24 is 100 nm.

Next, an absorption-layer precursor 25 was deposited on the Mo-containing layer 24, as shown in FIG. 2D. In the present embodiment, the absorption-layer precursor 25 was a mixed material of Cu, In and Ga, which can be deposited on the Mo-containing layer 24 through a respectively-sputtering process, a co-sputtering process, a respectively-electroplating process, or a co-electroplating process.

With reference to FIGS. 2D and 2E, after the absorption-layer precursor 25 was formed, the selenization process or the sulfation process was sequentially performed to transfer the absorption-layer precursor 25 into an absorption layer 25a, and the Mo-containing layer 24 into an ohmic contacting layer 24a. In the present embodiment, the selenization process was performed. The selenization process used in the present embodiment can be the process generally used in the art. The steps for performing the selenization process are shown as follow. First, the substrate 21 with the absorption-layer precursor 25 formed thereon was placed into a selenization furnace, and vacuum was generated to make the chamber pressure of the selenization furnace to be about 10⁻² ton. Next, the selenization furnace was heated to about 400-700 ° C., and an annealing process was performed for 20 mins to 3 hrs. The interior of the selenization furnace contained Se powders or was induced with H₂Se gas, so Se vapor with high pressure was formed. The high-pressure Se vapor can be diffused into the absorption-layer precursor 25 to transfer the absorption-layer precursor 25 into the absorption layer 25a. In addition, the Se vapor can also be diffused into the Mo-containing layer 24 to transfer the Mo-containing layer 24 into the ohmic contacting layer 24a, as shown in FIG. 2E. After the aforementioned process, the obtained ohmic contacting layer 24a was a MoSe₂ layer, and the obtained absorption layer 25a was a CIGS absorption layer.

Next, CdS was deposited on the absorption layer 25a to form a buffer layer 26 with any process generally used in the art, as shown in FIG. 2E.

Then, a ZnO thin layer (i.e. i-layer) and a ZnO transparent conductive film doped with Al were sequentially deposited on the buffer layer 26 to form a transparent conductive layer 27. Finally, Ni and Al were deposited on the transparent conductive layer to form a second electrode 28.

After the aforementioned process, a thin film solar cell of the present embodiment was obtained, which comprises: a substrate 21; a first electrode 22 disposed on the substrate 21; a barrier layer 23 disposed on the first electrode 22, wherein the material of the barrier layer 23 is a conductive material; an ohmic contacting layer 24a disposed on the barrier layer 23; an absorption layer 25a disposed on the ohmic contacting layer 24a; a buffer layer 26 disposed on the absorption layer 25a; a transparent conductive layer 27 disposed on the buffer layer 26; and a second electrode 28 disposed on the transparent conductive layer 27.

### Embodiment 2

The thin film solar cell and the method for manufacturing the same of the present embodiment are the same as those described in Embodiment 1, except that the material of the barrier layer 23 of the present embodiment was La doped with Al. Hence, during the sequential selenization process, the Al element contained in the barrier layer 23 was diffused into the absorption layer 25a, so the absorption layer 25a was gradiently doped with Al. Therefore, a graded absorption bandgap was obtained.

### Embodiment 3

The thin film solar cell and the method for manufacturing the same of the present embodiment are the same as those described in Embodiment 1, except that the material of the Mo-containing layer 24 of the present embodiment was Mo doped with Al. Hence, during the sequential selenization process, the Al element contained in the Mo-containing layer 24 was diffused into the absorption layer 25a, so the absorption layer 25a was gradiently doped with Al. Therefore, a graded absorption bandgap was obtained.

Although the present invention has been explained in relation to its preferred embodiment, it is to be understood that many other possible modifications and variations can be made without departing from the spirit and scope of the invention as hereinafter claimed.

What is claimed is:

1. A thin film solar cell, comprising:
a substrate;
a first electrode disposed on the substrate;
a barrier layer disposed on the first electrode, wherein the material of the barrier layer is a conductive material;
an ohmic contacting layer disposed on the barrier layer;
an absorption layer disposed on the ohmic contacting layer;
a buffer layer disposed on the absorption layer;
a transparent conductive layer disposed on the buffer layer; and
a second electrode disposed on the transparent conductive layer.

2. The thin film solar cell as claimed in claim 1, wherein the material of the barrier layer is Al, La, Ta, Ir, Os, or an alloy thereof.

3. The thin film solar cell as claimed in claim 2, wherein the material of the barrier layer is Al, La, or an alloy thereof.

4. The thin film solar cell as claimed in claim 1, wherein the material of the barrier layer is doped with B, Al or Ga.

5. The thin film solar cell as claimed in claim 1, wherein the ohmic contacting layer is a MoSe₂ layer.

6. The thin film solar cell as claimed in claim 5, wherein the thickness of the ohmic contacting layer is 1-150 nm.

7. The thin film solar cell as claimed in claim 1, wherein the first electrode is a Mo electrode.

8. The thin film solar cell as claimed in claim 1, wherein the substrate is a glass substrate, a metal substrate, or a plastic substrate.

9. The thin film solar cell as claimed in claim 8, wherein the metal substrate is a stainless substrate, a Ti substrate, a Cu substrate, or a Mo substrate.

10. The thin film solar cell as claimed in claim 1, wherein the absorption layer is a CIS absorption layer, a CIGS absorption layer, a CZTS absorption layer, or a CIAS absorption layer.

11. The thin film solar cell as claimed in claim 1, wherein the transparent conductive layer is ITO, ZnO doped with Al, or ZnO doped with In.

12. A method for manufacturing a thin film solar cell, comprising the following steps:
(A) providing a substrate;
(B) forming a first electrode on the substrate;
(C) forming a barrier layer on the first electrode, wherein the material of the barrier layer is a conductive material;
(D) forming a Mo-containing layer on the barrier layer;
(E) forming an absorption-layer precursor on the Mo-containing layer, and performing a selenization process or a sulfation process to transfer the absorption-layer precursor and the Mo-containing layer into an absorption layer and an ohmic contacting layer respectively;
(F) forming a buffer layer on the absorption layer;
(G) forming a transparent conductive layer on the buffer layer; and
(H) forming a second electrode on the transparent conductive layer.

13. The method as claimed in claim 12, wherein the material of the barrier layer is Al, La, Ta, Ir, Os, or an alloy thereof.

14. The method as claimed in claim 13, wherein the material of the barrier layer is Al, La, or an alloy thereof.

15. The method as claimed in claim 12, wherein the material of the barrier layer is doped with B, Al or Ga.

16. The method as claimed in claim 12, wherein the Mo-containing layer is a Mo layer, and the ohmic contacting layer is a MoSe₂ layer.

17. The method as claimed in claim 16, wherein the thickness of the ohmic contacting layer is 1-150 nm.

18. The method as claimed in claim 12, wherein the first electrode is a Mo electrode.

19. The method as claimed in claim 12, wherein the substrate is a glass substrate, a metal substrate, or a plastic substrate.

20. The method as claimed in claim 19, wherein the metal substrate is a stainless substrate, a Ti substrate, a Cu substrate, or a Mo substrate.

21. The method as claimed in claim 12, wherein the absorption layer is a CIS absorption layer, a CIGS absorption layer, a CZTS absorption layer, or a CIAS absorption layer.

22. The method as claimed in claim 12, wherein the transparent conductive layer is ITO, ZnO doped with Al, or ZnO doped with In.
